(19) United States
(12) Patent Application Publication
(10) Pub. No.: US 2013/0056047 A1
(43) Pub. Date: Mar. 7, 2013

(54) PHOTOVOLTAIC MODULE WITH SEALED PERIMETER AND METHOD OF FORMATION

(71) Applicants: Markus E. Beck, Scotts Valley, CA (US); Pedro Gonzalez, Fremont, CA (US)

(72) Inventors: Markus E. Beck, Scotts Valley, CA (US); Pedro Gonzalez, Fremont, CA (US)

(21) Appl. No.: 13/601,594

(22) Filed: Aug. 31, 2012

Related U.S. Application Data
(60) Provisional application No. 61/530,660, filed on Sep. 2, 2011.

(51) Int. Cl. H01L 31/048; H01L 31/0203

(52) U.S. Cl. 136/251; 438/66; 257/E31.117

(57) ABSTRACT

A photovoltaic module is formed by encasing the edge of the photovoltaic module with a dielectric while passing internal module conductors through the edge encased. The edge encasing may be an overmolded dielectric through which the internal conductors pass or connectors may be provided in the overmolded dielectric to allow for external connection to the module. The photovoltaic module can also include mechanical attachment points formed in the molded dielectric to allow the module to be attached to a support structure.

### CLAIM OF PRIORITY

This application claims priority under 35 U.S.C. §119(e) to U.S. Provisional Patent Application Ser. No. 61/530,660 filed on Sep. 2, 2011, which is hereby incorporated by reference in its entirety.

### TECHNICAL FIELD

The disclosed embodiments relate to a photovoltaic module with a sealed perimeter and methods for manufacturing photovoltaic modules.

### BACKGROUND

Photovoltaic (PV) modules are commonly installed and mounted in outdoor locations to allow for direct sunlight exposure. Outdoor installation exposes the modules to moisture in the form of precipitation and humidity, among others. Moisture can be harmful if it accesses the interior surfaces of the module. For example, moisture can promote corrosion of surfaces within the module. Moisture can also lead to structural damage if allowed to freeze within the module. A common location for moisture ingress is near a junction box that is mounted to a back surface of the module, which allows external electrical connections to the module.

As is shown in FIGS. 1 and 2, current PV modules 100 use a junction box 250 that allows the module 100 to be connected to other modules and/or electrical devices in a solar energy system. It is common to attach the junction box 250 to an outer surface of the module 100. For example, the junction box 250 can be installed adjacent to the back cover 240 of the module 100. The junction box 250 is commonly positioned over an opening 405 in the back cover 240 of a module. Positive and negative conductors within the module 100 are connected with external module conductors 120, 125 within the junction box 250. Accordingly, a plurality of external conductors of the module 100 may extend from the module 100 for such connections. As one example, shown in FIG. 1, first and second internal conductors 410, 415 of the module 100 are fed through the opening 405 in the back cover 240 and folded over to be flat with the back cover 240. To prevent the first and second conductors 410, 415 from shorting, the conductors can be folded back against the back cover 240 in opposing directions.

In existing modules, the junction box 250 is often attached to the module 100 using an adhesive layer 430 such as silicone based adhesives, urethanes, solar acrylic foam tape, or a liquid adhesive such as polyisobutylene (PIB). Once the junction box 250 has been attached to the module 100, external conductors 120, 125, which pass into the junction box 250, can be respectively soldered or otherwise electrically connected to the first and second conductors 410, 415. One purpose of the junction box 250 is to enclose the soldered or other electrical connections for safety reasons. Another purpose of the junction box 250 is to prevent moisture from accessing the inner surfaces of the module 100 through the opening 405 in the back cover 240. Bypass diodes employed in a solar insulation may also be housed within the junction box 250. While many recent improvements have been made with respect to waterproof sealing the opening 405, the possibility of water intrusion remains a constant concern. Accordingly, a PV module with improved resistance to water ingress through opening 405 is desired.

Existing PV modules 100 also generally have mounting hardware 115 attached, as shown in FIG. 2, on a frame 435 surrounding the module to permit installation of the module to a support structure. The existing mounting hardware 115 can be clips or mounting brackets. Such mounting hardware must be secured to a side edge of the PV module 100, which bears the risk of damaging the PV module 100. In addition, the external mounting brackets 115 provide an additional component that may fail and require maintenance while the PV module 100 is in use. It is therefore desirable to provide a better way of mounting a module to a support structure in the field.

### DESCRIPTION OF DRAWINGS

FIG. 1 is a cut away exploded view of an existing photovoltaic module.

FIG. 2 is a cut away bottom perspective view of an existing photovoltaic module.

FIG. 3 is a partially completed photovoltaic module in accordance with a first disclosed embodiment.

FIG. 3A is a cross-sectional view of FIG. 3 taken along section A-A in accordance with the first disclosed embodiment.

FIG. 3B is a cross-sectional view of FIG. 3 taken along section A-A in accordance with a second disclosed embodiment.

FIG. 4 is a top perspective view of an example photovoltaic module in accordance with the first disclosed embodiment.

FIG. 5 is a bottom perspective view of the photovoltaic module of FIG. 4 in accordance with the first disclosed embodiment.

FIG. 6 is bottom view of a photovoltaic module with a dielectric overmold in accordance with a third disclosed embodiment.

FIG. 6A is bottom view of a photovoltaic module with a dielectric overmold in accordance with a fourth disclosed embodiment.

FIG. 7 is a cross-sectional view of FIG. 4 taken along section A-A in accordance with the first disclosed embodiment.

FIG. 7A is a cross-sectional view of FIG. 4 taken along section A-A in accordance with a fifth disclosed embodiment.

FIG. 8 is a partial cutaway view of a photovoltaic module with an overmolded perimeter in accordance with a sixth disclosed embodiment.

FIG. 9 is a photovoltaic module with an overmolded perimeter and stiffening elements in accordance with a seventh disclosed embodiment.

FIG. 10 is a photovoltaic module with an overmolded perimeter and stiffening elements in accordance with an eighth disclosed embodiment.

FIG. 11 is a photovoltaic module with an overmolded perimeter and stiffening elements in accordance with a ninth disclosed embodiment.

FIG. 12 is a photovoltaic module with an overmolded perimeter and stiffening elements in accordance with a tenth disclosed embodiment.

FIG. 13 is a photovoltaic module with an overmolded perimeter and stiffening elements in accordance with an eleventh disclosed embodiment.

### DETAILED DESCRIPTION

In the following detailed description, reference is made to the accompanying drawings, which form a part hereof, and in which specific embodiments are illustrated that may be practiced. These embodiments are described in sufficient detail to enable those skilled in the art to make and use them. It is to be understood that structural, logical, or procedural changes may be made to the specific embodiments disclosed without departing from the spirit and scope of the invention. Other features, objects, and advantages will be apparent from the description, drawings, and claims.

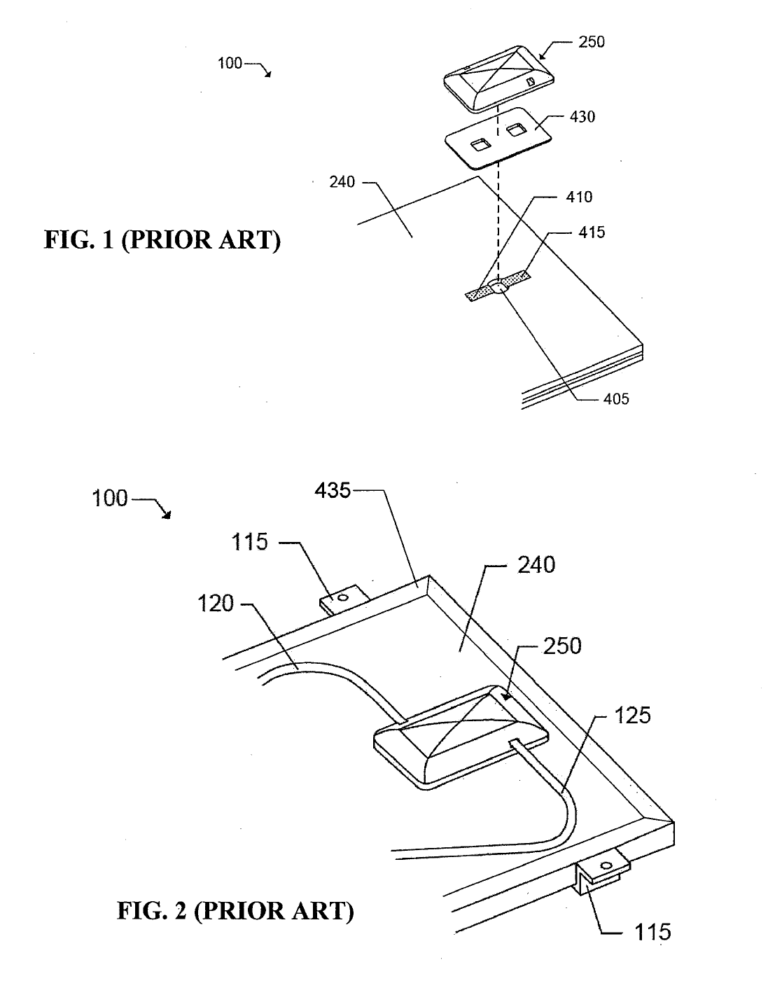

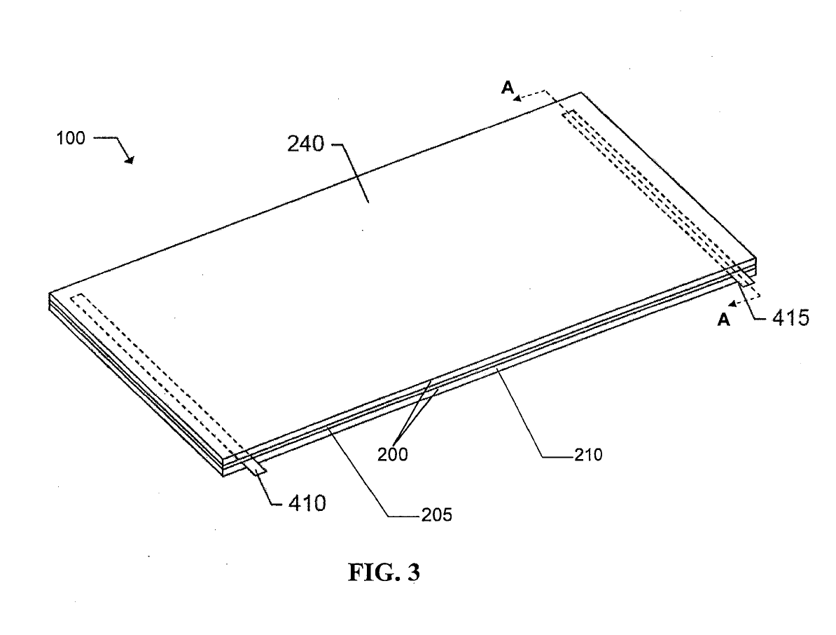

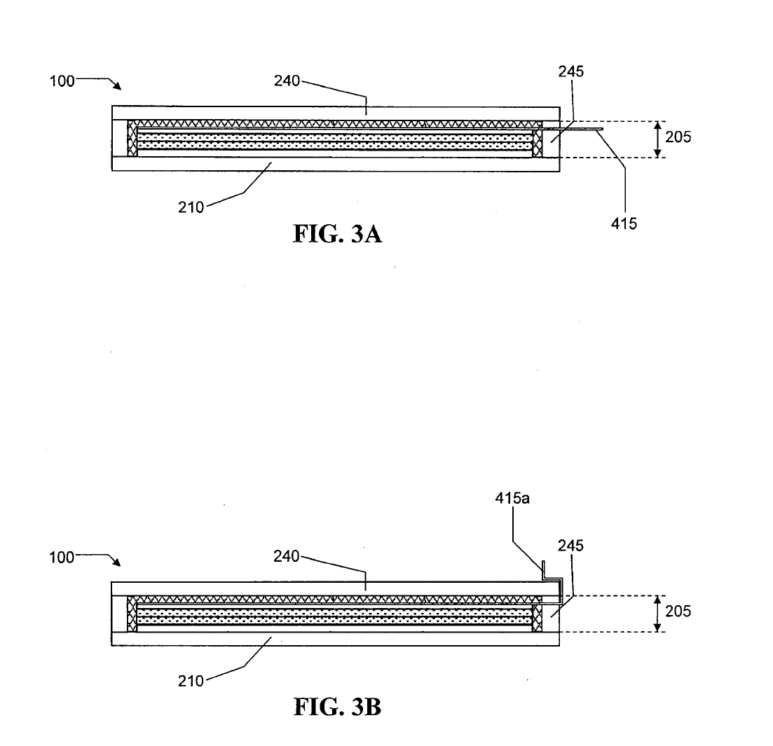

To eliminate concerns of water intrusion through the opening 405 and junction box 250 in the back cover 240 shown in FIGS. 1 and 2, one embodiment described below and shown in FIG. 3 is used. In the figure, the opening 405 in the back cover 240 is eliminated, and first and second conductors 410, 415 are passed through a gap 205 formed at the periphery of the module 100 between the front cover 210 and the back cover 240. The ends of the conductors 410, 415 may extend beyond the edges 200 of the back cover 240 and front cover 210 to provide a point at which an electrical connection may be made. This eliminates the need for the junction box 250 and the module manufacturing process is simplified.

After the conductors 410, 415 have been extended through the gap 205 to outside of the module 100, they can be configured to allow for interconnection to other devices. In the present embodiment, the conductors 410, 415 are shown as exiting at the corners of the PV module 100. In other embodiments, the conductors 410, 415 may be placed internally of the module 100 so they extend from the module 100 at any desired point along the perimeter of the module 100, including along the centerline, at the ends, at the corners, or spaced between the center and a corner of module 100 as desired.

FIG. 3A shows a cross-sectional view of the partly completed PV module 100 of FIG. 3. The internal layers between the front cover 210 and back cover 240 may include any configuration known in the art. As shown in FIG. 3A, the gap 205 between the front cover 210 and back cover 240 extends around the entire periphery of module 100 and is filled with a moisture barrier edge seal 245 formed, for example, of a dielectric material such as acrylonitrile butadiene styrene (ABS), acrylic (PMMA), celluloid, cellulose acetate, cycloolefin copolymer (COC), ethylene-vinyl acetate (EVA), ethylene vinyl alcohol (EVOH), fluoroplastics (PTFE), ionomers, Kydex®, liquid crystal polymer (LCP), polyacetal (POM), polyacrylates, polyacrylonitrile (PAN), polyamide (PA), polyamide-imide (PAI), polyaryletherketone (PAEK), polybutadiene (PBD), polybutylene (PB), polybutylene terephthalate (PBT), polycaprolactone (PCL), polychlorotrifluoroethylene (PCTFE), polyethylene terephthalate (PET), polycyclohexylene dimethylene terephthalate (PCT), polycarbonate (PC), polyhydroxyalkanoates (PHAs), polyketone (PK), polyester, polyethylene (PE), polyetheretherketone (PEEK), polyetherketoneketone (PEKK), polyetherimide (PEI), polyethersulfone (PES), polyethylenechlorinates (PEC), polyimide (PI), polyactic acid (PLA), polymethylpentene (PMP), polyphenylene oxide (PPO), polyphenylene sulfide (PPS), polyphthalamide (PPA), polypropylene (PP), polystyrene (PS), polysulfone (PSU), polytrimethylene terephthalate (PTT), polyurethane (PU), polyvinyl acetate (PVA), polyvinyl chloride (PVC), polyvinylidene chloride (PVDC), styrene-acrylonitrile (SAN), butyl rubber (PIB), EPDM rubber, santoprene, neoprene, or silicone sealant. The edge sealant 245 also encapsulates the first and second conductors 410, 415. In another embodiment, shown in FIG. 3B, the conductors (e.g. 415a) may extend from the edge of the module 100 and fold back over the back cover 240 to permit connection to the conductor 415a at the back side of the module 100.

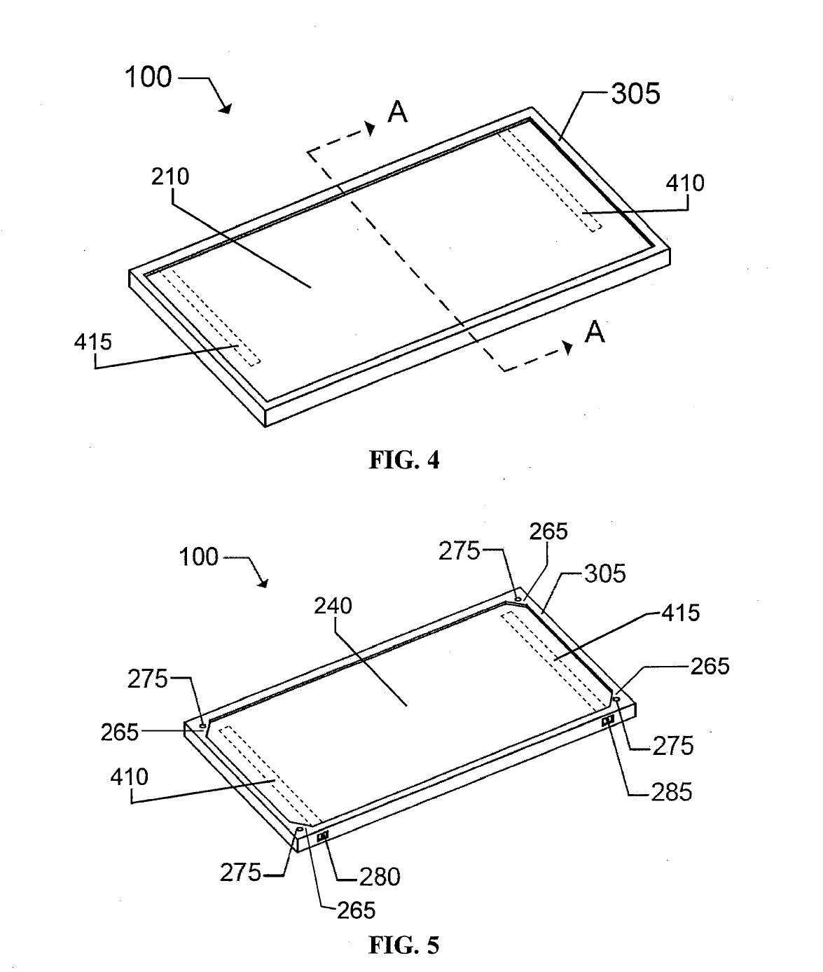

In another embodiment, shown in FIGS. 4 and 5, which respectively show a top side and a back side of a PV module 100, the external periphery of module 100 may be over molded with a dielectric material 305 such as a thermoset plastic or any other suitable material. The manufacturing process for forming this overmolded dielectric 305 is described in more detail below. The dielectric 305 can include any flowable dielectric such as a thermoplastic or a thermoplastic elastomer (TPE). The dielectric 305 may also include high temperature amorphous resins or semi-crystalline resins. These dielectrics include acetal, liquid crystal polymer (LCP), polyester, polyamide, polyethylene (PE), polypropylene (PP), polyphenylene sulfide (PPS), polyetherimide (PEI), polysulfone, EPDM rubber, santoprene, neoprene, polycarbonate, aromatic urethane, aliphatic urethane, or acrylic.

The dielectric overmold 305 serves several important functions. The dielectric overmold 305 provides structural integrity to the module 100. The dielectric overmold 305 can also fill the peripheral gap between the front cover 210 and back cover 240 and serves to secure the back cover 240 to the front cover 210. Further, the dielectric overmold 305 serves as a moisture barrier around the entire periphery of the PV module 100. In one embodiment, the dielectric 305 can be molded such that it possesses a uniform thickness around the entire periphery of the module 100. In another embodiment, the dielectric 305 may be molded such that it is thicker closer to the corners of the module 100 to provide increased strength at these locations. The increased thickness would have the advantage of making the overmolded dielectric 305 stronger at the corners for supporting mechanical attachment points 275, discussed in further detail below. Similarly and in another embodiment, overmold dielectric material 305 may be formed across the back cover 240 at the corners to form angled bracing 265 as shown in FIG. 5. The angled bracing 265 serves to provide additional strength at the mechanical attachment points 275, as well as additional support to the module 100 in general and back cover 240 in particular.

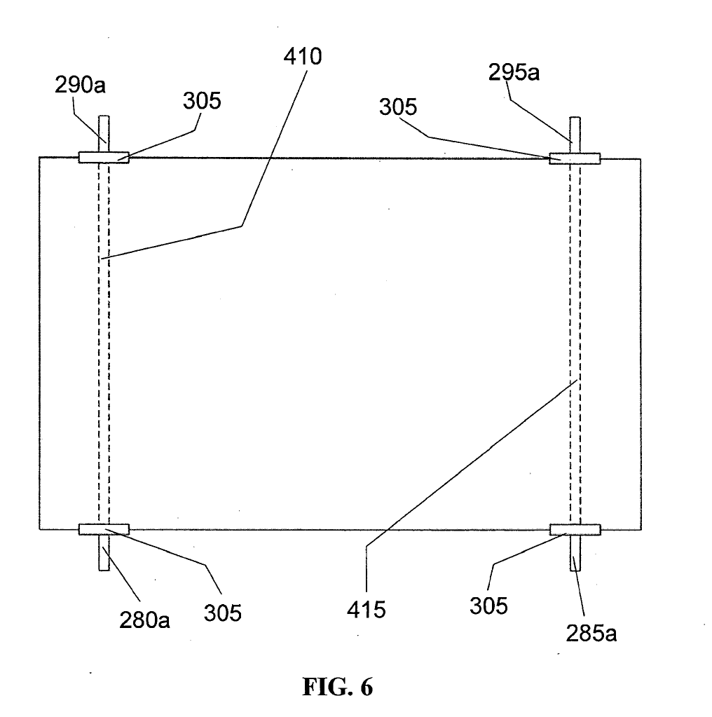

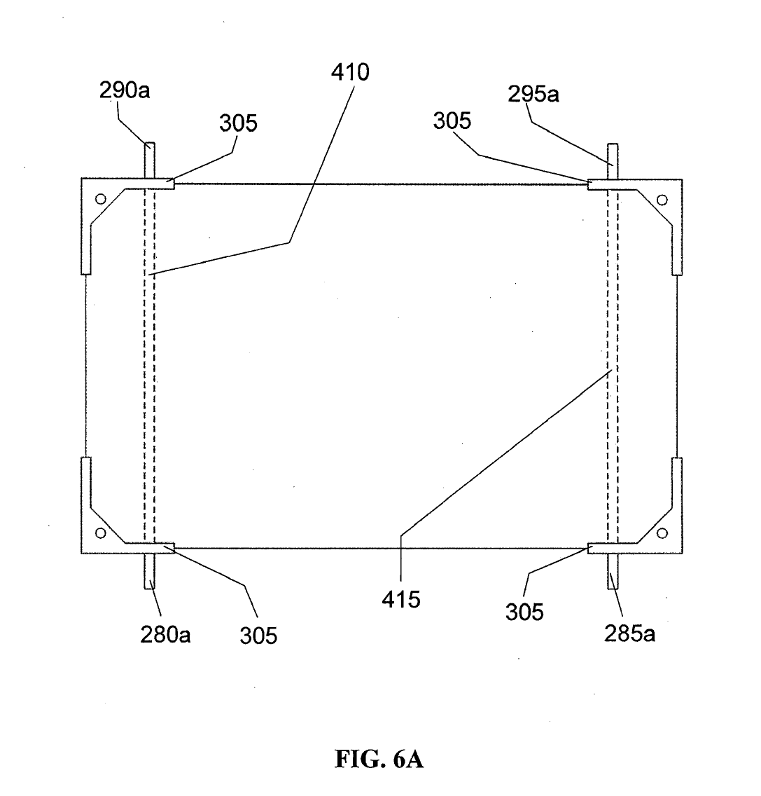

In other embodiments, shown in FIGS. 6 and 6A from a bottom view, the overmolded dielectric 305 may be formed only along certain segments of the edge 200 of the PV module 100. In these embodiments, other segments of the edge 200 of the PV module 100 would lack the overmolded dielectric 305. For example, the overmolded dielectric 305 may be formed only at the corners or along the length of the PV module 100 surrounding the terminals 280a, 285a, 290a, 295a of the internal conductors 410, 415 at the points where the terminals 280a, 285a, 290a, 295a exit from the module 100.

The dielectric overmold 305 can also provide electrical connectors for allowing electrical connections to the module 100. For example, as shown in FIG. 5, the backside view of module 100, the dielectric overmold 305 can include electrical connections formed as a first connector 280 and a second connector 285, which are electrically connected to and serve as the electrical connectors for the first and second conductors 410, 415 respectively. Thus, the first and second connectors 280, 285 serve as positive and negative connectors for the module 100, allowing connection of a module 100 to other PV modules or other desired components of a photovoltaic system. If more than two terminals extend from the module 100, respective connectors can be provided for each.

In another embodiment, also shown in FIG. 6, the internal conductors 410, 415 may be encapsulated by and extend through the overmolded dielectric 305 without terminating in a connector 280, 285. In this case, an electrical connection of a module 100 by external conductors may be accomplished, for example, by soldering, welding, clips, or other electrical connection means known in the art that cause the external conductors to be electrically attached to the terminals 280a, 285a, 290a, 295a of the internal conductors 410, 415. Also shown in FIGS. 6 and 6A, the terminals 280a, 285a, 290a, 295a may extend from different sides of the module 100, including opposite sides of the edge 200 of the module 100, and more than two terminals, e.g. 280a, 285a, 290a, 295a can be brought out from the side edges 200 of the module 100.

In one embodiment shown in FIGS. 3-5, a two-connector (280, 285) design is utilized. In another embodiment, shown in FIGS. 6 and 6A, the PV module 100 can be created with more connectors or terminals depending on the number of terminals or connectors desired on the outside the module 100, for example, a three or four terminal design.

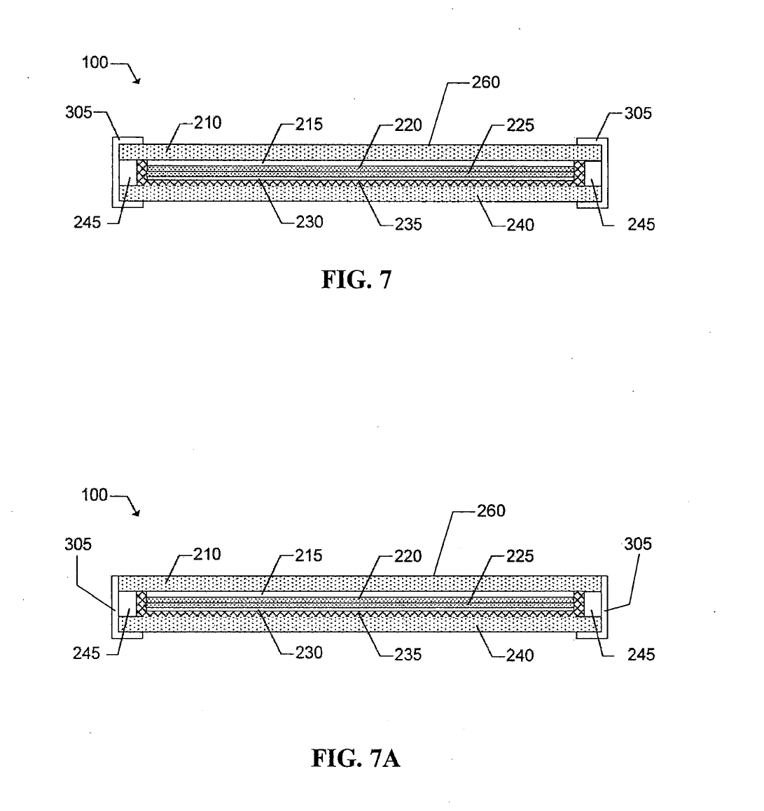

As is shown in FIG. 7, a cross sectional view along A-A of FIG. 4, the overmolded dielectric 305 is molded over both the front cover 210 and the back cover 240, creating a “C” shaped cross section. Other embodiments may utilize an overmolded dielectric that is only molded over the front cover 210 or the back cover 240 and edge 200 of module 100, creating an “L” shaped cross section, as shown in FIG. 7A, which is a cross sectional view along A-A of FIG. 4 according to another embodiment. As further illustrated in FIGS. 7 and 7A, the overmolded dielectric 305 may also be applied at a periphery of a module 100 that is sealed between the front cover 210 and back cover 240 using an edge sealant 245, as was discussed above.

FIGS. 7 and 7A also show examples of the internal structure of a PV module 100. The module 100 can include a front cover 210 that has an outer surface, which faces the outward from module 100, and an inner surface, which faces the internal structure of the PV module 100, a front contact layer 215 adjacent to the front cover 210, a semiconductor window layer 220 adjacent to the front contact layer 215, a semiconductor absorber layer 225 adjacent to the semiconductor window layer 220, and a back contact layer 230 adjacent to the semiconductor absorber layer 225. An interlayer 235 may also be provided for the module 100. Finally, a back cover 240 may be placed with an inner surface adjacent to the interlayer 235 and an outer surface facing outward from the module 100 to protect the plurality of layers from moisture ingress or physical damage. An anti-reflective coating 260 may also be formed on the outer surface of the front cover 210. The various layers illustrated in FIGS. 7 and 7A merely form one example of an internal module construction that can be employed. As noted, the PV module 100 can also include an edge sealant 245 and a dielectric overmold 305 encasing the perimeter of the module.

The interlayer 235 may serve several important functions. The interlayer 235 may serve as a moisture barrier between the back cover 240 and the plurality of layers. This helps prevent moisture-induced corrosion from occurring inside the module 100 and may increase the module's life expectancy. The interlayer 235 may also serve as an electrical insulator between the plurality of layers and the back cover 240.

In one embodiment, the layers discussed above are formed into a plurality of PV cells within a module that can be connected to common positive and negative conductors 410, 415. For example, a first conductor 410 can be attached to the front contact layer 215 of the first PV cells in the series, and a second conductor 415 can be attached to the back contact layer 230 of the last PV cells in the series. In other embodiments, the module can include any suitable arrangement of series and parallel connections between the PV cells.

In one embodiment, an edge sealant 245, shown in FIG. 7, can be applied to envelop the first and second conductors 410, 415 after the first and second conductors 410, 415 have been formed in the PV module 100 to extend beyond the external periphery of the module, as shown in FIG. 3. This prevents moisture from entering the module 100 proximate the exit locations of the conductors 410, 415. The edge sealant 245 can also be added around the entire perimeter of the module 100 as discussed above. Consequently, the edge sealant 245 can protect the perimeter of the module 100 from moisture ingress. The edge sealant 245 can also serve as an adhesive that bonds the front cover 210 to the back cover 240.

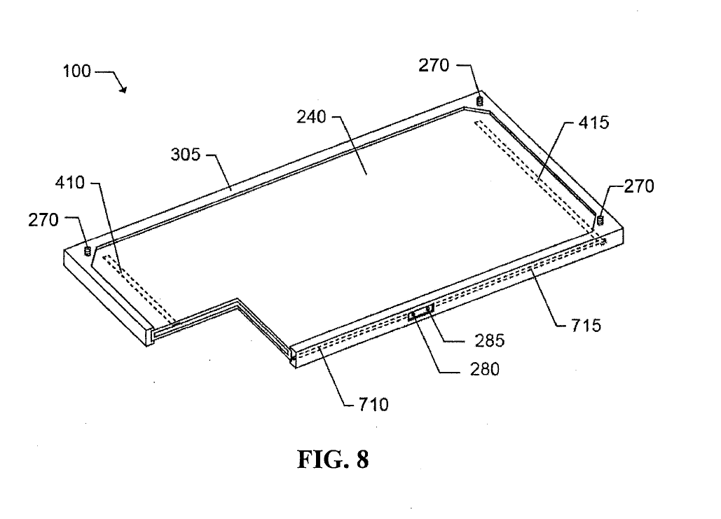

In another embodiment, shown by way of example in FIG. 8, the first and second connectors 280, 285 discussed above with respect to FIG. 5 can be located near each other to simplify the process of connecting the module 100 to other devices. Positioning the first and second connectors 280, 285 near each other can be accomplished by buses 710, 715 within the module 100 to relocate the connector ends of internal conductors 410, 415 to exit the module 100 at approximately the center of the long edge. Consequently, the first conductor 410 can be electrically connected to the first connector 280 and associated connector by a first bus 710. Likewise, the second conductor 415 can be electrically connected to the second connector 285 by a second bus 715. External connectors can be connected to the connector ends 280, 285 of the internal conductors 410, 415 at approximately the center of the PV module 100, rather than at its corners. In one embodiment, the buses 710, 715 can be formed within the dielectric overmold 305. In another embodiment, the buses 710, 715 can be formed within and along an edge of the PV module 100, for example, adjacent to the front cover 210 or back cover 240, or formed within the edge sealant 245 before overmolding.

In one embodiment, the connectors 280, 285, wherever located on the overmolded dielectric 305, can include, for example, a connector that is keyed to a corresponding external connector of an external conductor. The keyed connectors help ensure that, for example, the proper external connector is connected to the positive and negative internal conductors by keying each connector 280, 285 to a respective mating external connector. In an alternative embodiment, the connectors 280, 285 can include a locking connector designed to lock with its respective corresponding external locking connector of an external conductor. In another alternative embodiment, the connectors 280, 285 are both keyed to a specific corresponding connector and contain a locking element. The keyed and/or locking connectors will hold external conductors to connectors 280, 285, which facilitates stable external connections to module 100. The locking connector may include those known in the art such as a push-in and twist-lock plug, a locking tab that engages with a slot on the external connector to hold the external connector in place, a threaded element that screws onto a threaded plug, and a latched plug that engages in a locking jack.

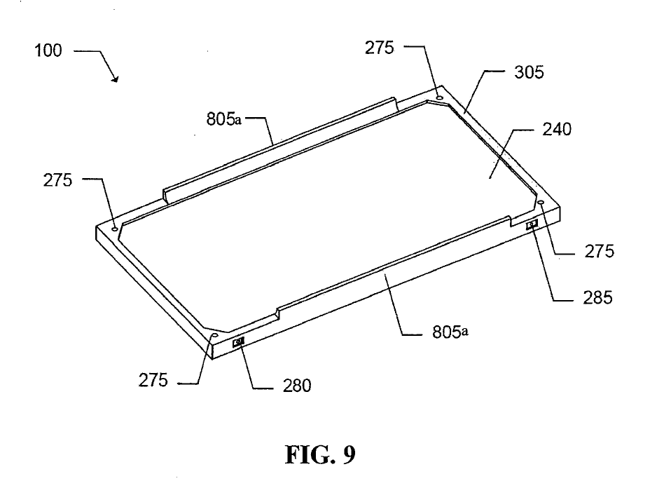

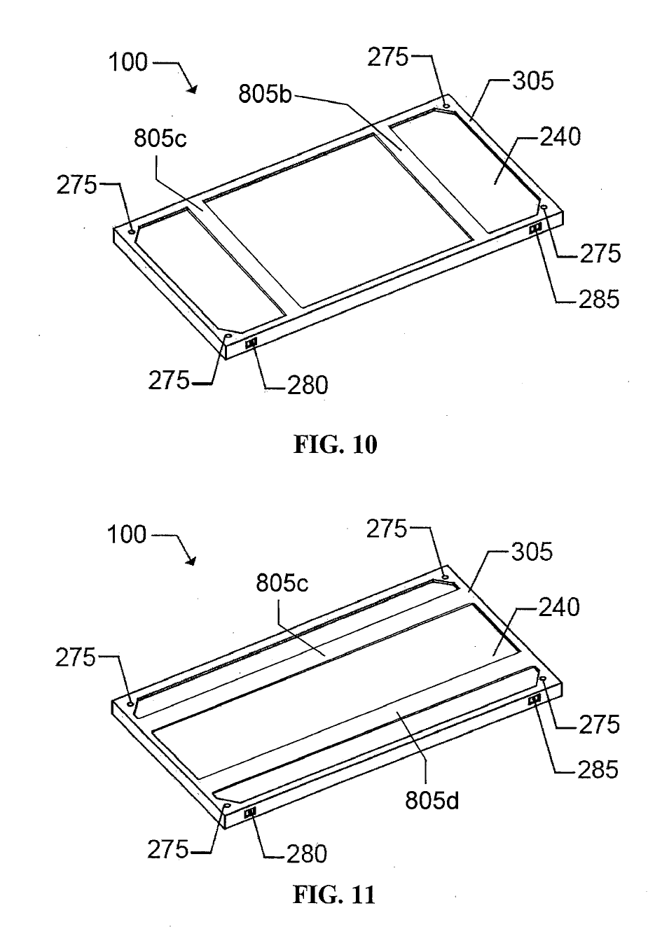

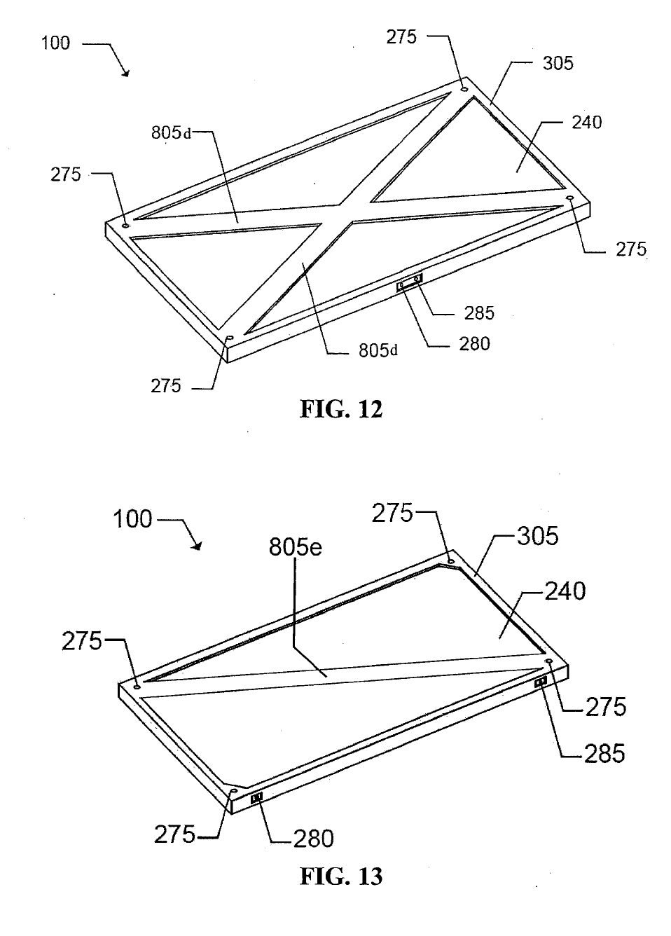

In other embodiments shown in FIGS. 9-13, the dielectric overmold 305 can further include stiffening elements 805a, 805b, 805c, 805d, 805e provided on the backside of a module 100 to enhance the structural integrity of the module 100. The stiffening elements 805a, 805b, 805c, 805d, 805e can be provided as ribs to increase the module's rigidity along a particular axis or axes. The stiffening elements 805a, 805b, 805c, 805d, 805e can be made from the same material used to form the dielectric overmold 305. Alternately, the stiffening elements 805a, 805b, 805c, 805d, 805e can be formed of any other suitable material. In one example, the stiffening elements 805a, 805b, 805c, 805d, 805e may further include non-plastic inserts to the overmolded dielectric 305, such as metal or carbon fiber inserts to enhance the rigidity of the module 100. The stiffening elements 805a can be positioned along the length the module as shown in FIG. 9. In two other embodiments, as shown in FIGS. 10 and 11, the stiffening elements 805b, 805c can be formed across the back cover 240, transecting either the length or the width of the PV module 100, offset from the peripheral edges of the module 100. In other embodiments, the stiffening elements 805d, 805e can respectively diagonally crisscross or just diagonally cross the back cover 240 as shown in FIGS. 12 and 13.

In another embodiment, integral mechanical attachment points may be formed on or in the dielectric overmold 305 to eliminate the need for the external mounting brackets 115 shown in FIG. 2. The mechanical attachment points 270 (FIG. 8) or 275 (FIGS. 5 and 9-13) enable mounting the module 100 to a mounting or support structure without the additional maintenance or risk of failure that the external mounting brackets 115 present. The mechanical attachment points 270, 275 may be formed from the material used for the overmolding or may include sturdy mechanical structures which are overmolded by the dielectric overmolding 305. The attachment points 270, 275 may be positioned at each of the four corners of the module 100 as seen for example in FIGS. 5 and 9-13, or may be positioned along the sides of the module as desired. Alternately, more or fewer than four mechanical attachment points may be included, depending on the type of installation and the severity of weather the module 100 will likely encounter.

The mechanical attachment points may be either female or male. If the mechanical attachment points are female, they may include threaded nuts 275 molded within the dielectric overmold 305, as shown in FIGS. 5 and 9-13. Alternately, if the mechanical attachment points are male, they may include threaded bolts 270 molded within the dielectric overmold 305, as shown in FIG. 8. The male or female attachment points may be formed of metal hardware that is molded in place by dielectric overmold 305. For example, the threaded bolts 270 may be cap head bolts where the cap head is molded within the dielectric overmold 305, thereby preventing the bolt 270 from rotating when a nut is being installed onto the bolt 270.

As used herein, the term “overmold” includes all molding processes, such as multi-shot, multi-component, in-mold assembly, two-shot, double-shot, multi-inject, and insert molding. Overmolding also includes molding processes where two or more materials are combined to produce a single part. In one example, overmolding can seamlessly combine a rigid substrate, such as a PV module, with a dielectric material in the manner discussed above. During the overmolding process, the partially completed module 100 (e.g. FIG. 3) is inserted into an injection molding machine. A flowable dielectric is then injected into the mold where it meets and adheres to the perimeter of the partially completed module 100.

While various embodiments have been described herein, various modifications and changes can be made. Accordingly, the disclosed embodiments are not to be considered as limiting as the invention is defined by the scope of the pending claims.

What is claimed is:

1. A photovoltaic module comprising:
a front cover;
a back cover, wherein the front cover and the back cover terminate at a common perimeter;
a plurality of PV cells provided between the front cover and the back cover;
a first conductor which passes through a gap between the front cover and the back cover at the common perimeter and is electrically coupled to at least one of the PV cells;
a second conductor which passes through a gap between the front cover and the back cover at the common perimeter and is electrically couple to at least another one of the PV cells; and
a dielectric material encasing at least a segment of the common perimeter.

2. The photovoltaic module of claim 1, wherein the dielectric material is overmolded onto the common perimeter.

3. The photovoltaic module of claim 1, wherein the dielectric material encases the entire common perimeter.

4. The photovoltaic module of claim 2, wherein the first conductor is formed at a first end of the photovoltaic module and the second conductor is formed at a second end of the photovoltaic module.

5. The photovoltaic module of claim 2, wherein the first conductor is formed in a first corner of the photovoltaic module and the second conductor is formed in a second corner of the photovoltaic module.

6. The photovoltaic module of claim 2, wherein the first and second conductors are formed at ends of the photovoltaic module.

7. The photovoltaic module of claim 2, wherein the first and second conductors are formed substantially along a centerline of the photovoltaic module.

8. The photovoltaic module of claim 2, wherein the dielectric material is formed across at least a portion of a corner of the back cover to form an angled bracing.

9. The photovoltaic module of claim 2, wherein the dielectric material comprises at least one mechanical attachment point for connecting the photovoltaic module to a support structure.

10. The photovoltaic module of claim 2, wherein the dielectric material is formed such that it overlaps at least a portion of the front cover and at least a portion of the back cover.

11. The photovoltaic module of claim 2, wherein the dielectric material is formed such that it overlaps at least a portion of the front cover.

12. The photovoltaic module of claim 2, wherein the dielectric material is formed such that it overlaps at least a portion of the back cover.

13. The photovoltaic module of claim 2, further comprising at least one stiffening element that is integral to the dielectric material.

14. The photovoltaic module of claim 1, wherein a portion of the first conductor extends beyond the common perimeter.

15. The photovoltaic module of claim 2, wherein the first and second conductors extend out of the dielectric material.

16. The photovoltaic module of claim 2, wherein an exposed first connector is formed within the dielectric material at the first conductor, and an exposed second connector is formed within the dielectric material at the second conductor.

17. The photovoltaic module of claim 2, further comprising a first bus, wherein the first bus connects the first conductor to a first connector.

18. The photovoltaic module of claim 2, wherein the dielectric material has a uniform thickness.

19. The photovoltaic module of claim 2, wherein the dielectric material has a thickness at a first location on the common perimeter that is greater than a thickness at a second location on the common perimeter.

20. The photovoltaic module of claim 1, wherein the first conductor passes through the gap between the front cover and the back cover at a first point and a second point along the common perimeter to form a first terminal and a second terminal.

21. A photovoltaic module comprising:
a front cover;
a back cover, wherein the front cover and the back cover terminate at a common perimeter;
a plurality of PV cells provided between the front cover and the back cover; and
a dielectric material encasing at least a segment of the common perimeter.

22. The photovoltaic module of claim 21, further comprising at least one stiffening element formed integral to the dielectric material.

23. The photovoltaic module of claim 21, wherein the dielectric material comprises at least one mechanical attachment point for connecting the photovoltaic module to a support structure.

24. The photovoltaic module of claim 22, wherein the dielectric material is overmolded onto the common perimeter.

25. The photovoltaic module of claim 22, wherein the dielectric material encases the entire common perimeter.

26. The photovoltaic module of claim 23, wherein the dielectric material is formed across at least a portion of a corner of the back cover to form an angled bracing.

27. A method for manufacturing a photovoltaic module, the method comprising:
forming a front cover;
forming a back cover, wherein the front cover and the back cover terminate at a common perimeter;
forming a plurality of PV cells between the front cover and the back cover;
forming a first conductor, wherein the first conductor passes through a gap between the front cover and the back cover at the common perimeter and is electrically coupled to at least one of the PV cells;
forming a second conductor, wherein the second conductor passes through a gap between the front cover and the back cover at the common perimeter and is electrically coupled to at least a second of the PV cells; and
forming a dielectric material over at least a segment of the common perimeter.

28. The method of claim 27, wherein the step of forming a dielectric material comprises overmolding the dielectric material over the common perimeter.

29. The method of claim 27, wherein the dielectric material is formed over the entire common perimeter.

30. The method of claim 27, further comprising:
forming the first conductor such that a portion of the first conductor extends beyond the common perimeter;
folding the portion of the first conductor that extends beyond the common perimeter over an outer surface of at least one of the front cover or back cover.

31. The method of claim 27, further comprising forming angled bracing in at least a portion of a corner of the back cover.

32. The method of claim 27, further comprising forming a mechanical attachment point within the dielectric material.

33. The method of claim 27, wherein the step of forming the dielectric material over the common perimeter comprises forming the dielectric material such that it overlaps at least a portion of both the front cover and the back cover.

34. The method of claim 27, wherein the step of forming the dielectric material over the common perimeter comprises forming a dielectric such that it overlaps at least a portion of the front cover.

35. The method of claim 27, wherein the step of forming the dielectric material over the common perimeter comprises forming the dielectric material such that it overlaps at least a portion of the back cover.

36. The method of claim 27, further comprising forming a stiffening element that is integral to the dielectric material.

37. The method of claim 27, further comprising forming a first connector that is integral to the dielectric material.

38. The method of claim 27, wherein the forming a dielectric material over the common perimeter step comprises injection molding.

39. The method of claim 27, wherein the dielectric material is formed with a uniform thickness.

40. The method of claim 27, wherein the dielectric material is formed with a thickness at a first location on the common perimeter that is greater than a thickness at a second location on the common perimeter.

41. The method of claim 27, wherein the first conductor is formed to pass through the gap at a first point and a second point along the common perimeter to form a first terminal and a second terminal.
